(19) United States
(12) Patent Application Publication
(10) Pub. No.: US 2026/0229996 A1
(43) Pub. Date: Aug. 6, 2026

(54) CONSTANT ON TIME SWITCHING CONVERTER

(71) Applicant: TEXAS INSTRUMENTS INCORPORATED, Dallas, TX (US)

(72) Inventors: Benjamin M MCCUE, Knoxville, TN (US); Ryan LIND, Knoxville, TN (US); Ronnie BEAN, Lenoir City, TN (US)

(21) Appl. No.: 19/043,437

(22) Filed: Feb. 1, 2025

(51) Int. Cl. H02M 3/158

(52) U.S. Cl. CPC H02M 3/1582

(57) ABSTRACT

A circuit includes first, second, third and fourth transistors, a buck control circuit, and a boost control circuit. The second transistor is coupled to the first transistor. The fourth transistor is coupled to the third transistor. The buck control circuit has a first output coupled to a control terminal of the first transistor, and a second output coupled to a control terminal of the second transistor. The boost control circuit includes a flip-flop, a first timer, and a second timer. The flip-flop has a first output coupled to a control terminal of the first transistor, a second output coupled to a control terminal of the second transistor, and an input. The first timer has an output coupled to the input of the flip-flop. The second timer has an output coupled to the input of the flip-flop.

### BACKGROUND

A switching converter is an electronic circuit that converts an input direct current (DC) voltage into one or more DC output voltages that are higher or lower in magnitude than the input DC voltage. A switching converter that generates an output voltage lower than the input voltage is termed a buck or step-down converter. A switching converter that generates an output voltage higher than the input voltage is termed a boost or step-up converter. A switching converter that generates an output that is either higher or lower than the input voltage is termed a buck-boost converter. Switching converters are widely used to power electronic devices, particularly battery powered devices, such as portable cellular phones, laptop computers, and other electronic systems in which efficient use of power is desirable.

### SUMMARY

In one example, a circuit includes first, second, third and fourth transistors, a buck control circuit, and a boost control circuit. The first transistor has a first terminal, a second terminal, and a control terminal. The second transistor has a first terminal coupled to the second terminal of the first transistor, a second terminal coupled to a reference terminal, and a control terminal. The third transistor has a first terminal, a second terminal, and a control terminal. The fourth transistor has a first terminal coupled to the second terminal of the third transistor, a second terminal coupled to the reference terminal, and a control terminal. The buck control circuit has a first output coupled to the control terminal of the first transistor, and a second output coupled to the control terminal of the second transistor. The boost control circuit includes a flip-flop, a first timer, and a second timer. The flip-flop has a first output coupled to the control terminal of the first transistor, a second output coupled to the control terminal of the second transistor, and an input. The first timer has an output coupled to the input of the flip-flop. The second timer has an output coupled to the input of the flip-flop.

In another example, an apparatus includes first, second, third, and fourth transistors, a buck control circuit, and a boost control circuit. The first transistor has a first terminal, a second terminal, and a control terminal. The second transistor has a first terminal coupled to the second terminal of the first transistor, a second terminal coupled to a reference terminal, and a control terminal. The third transistor has a first terminal, a second terminal, and a control terminal. The fourth transistor has a first terminal coupled to the second terminal of the third transistor, a second terminal coupled to the reference terminal, and a control terminal. The buck control circuit has a first output coupled to the control terminal of the first transistor, and a second output coupled to the control terminal of the second transistor. The boost control circuit has a first output coupled to the control terminal of the third transistor, and a second output coupled to the control terminal of the fourth transistor. The boost control circuit includes a first timer and a second timer. The first timer is configured to turn off the fourth transistor responsive to the apparatus operating in a boost mode. The second timer is configured to turn off the fourth transistor responsive to the apparatus operating in a buck-boost mode.

In a further example, a system includes an input terminal, an output terminal, first, second, third, and fourth transistors, an inductor, a buck control circuit, and a boost control circuit. The input terminal is configured to receive an input voltage. The output terminal is configured to provide an output voltage. The first transistor has a first terminal coupled to the input terminal, a second terminal, and a control terminal. The second transistor has a first terminal coupled to the second terminal of the first transistor, a second terminal coupled to a reference terminal, and a control terminal. The third transistor has a first terminal coupled to the output terminal, a second terminal, and a control terminal. The fourth transistor has a first terminal coupled to the second terminal of the third transistor, a second terminal coupled to the reference terminal, and a control terminal. The inductor has a first terminal coupled to the first terminal of the second transistor, and a second terminal coupled to the first terminal of the fourth transistor. The buck control circuit has a first output coupled to the control terminal of the first transistor, and a second output coupled to the control terminal of the second transistor. The buck control circuit includes a first timer configured to turn off the first transistor responsive to the system operating in a buck mode or a buck-boost mode. The boost control circuit has a first output coupled to the control terminal of the third transistor, and a second output coupled to the control terminal of the fourth transistor. The boost control circuit includes a second timer and a third timer. The second timer is configured to turn off the fourth transistor responsive to the system operating in a boost mode. The third timer is configured to turn off the fourth transistor responsive to the system operating in the buck-boost mode.

### BRIEF DESCRIPTION OF THE DRAWINGS

FIG. 1 is a block diagram of an example constant on-time buck-boost switching converter.

FIG. 2 is a schematic diagram of an example buck control circuit suitable for use in the switching converter of FIG. 1.

FIG. 3 is a schematic diagram of an example boost control circuit suitable for use in the switching converter of FIG. 1.

FIG. 4 is a schematic diagram of an example mode select circuit suitable for use in the switching converter of FIG. 1.

FIG. 5 shows examples of inductor current in the switching converter of FIG. 1 in buck, buck-boost, and boost modes.

FIG. 6 is a graph of example signals during buck-boost operation of the constant on-time switching converter of FIG. 1.

FIG. 7 is a graph comparing example ripple current in the switching converter of FIG. 1 to ripple current in a buck-boost converter using four transistor switching.

FIG. 8 is a block diagram of an example battery charging system that includes the switching converter of FIG. 1.

### DETAILED DESCRIPTION

Applications that use a switching converter may be subject to a variety of requirements. Some applications require that the converter provide fast transient response, and some applications require that the converter provide fast transient response with low output capacitance. For example, universal serial bus (USB) power delivery (USB-PD) applications require fast transient response (3-5%) with a maximum output capacitance of 10 microfarads.

Constant on-time (COT) control can be used to provide fast transient response in buck and boost converters. However, use of COT control in buck-boost converters is problematic because the COT control mechanism can be difficult to adapt to control two independent half-bridges. The switching converters described herein have input/output voltage dependent buck high-side and boost low-side on-times that allow the converter to operate at a relatively fixed switching frequency over a wide range of operating voltages, including in the buck-boost region. In the buck-boost region of operation, the switching converter initiates a fixed boost low-side on-time at the beginning of each cycle. This boost low-side on-time is set high enough to force the buck half-bridge to modulate periodically to regulate the output voltage at the desired switching frequency, but low enough to maintain low inductor current ripple. Such operation may be described as pseudo-buck operation.

The switching converter implements two-transistor, periodic buck-boost COT control that uses a relatively narrow boost pulse in the buck-boost region to provide converter operation in pseudo-buck mode. The boost pulse provided for pseudo-buck operation may be selected to be just wide enough to force the buck half-bridge to modulate periodically to regulate the output voltage at the desired switching frequency, but narrow enough to maintain low inductor current ripple. The pseudo-buck mode allows a single comparator to reliably modulate two independent half-bridges with low current ripple.

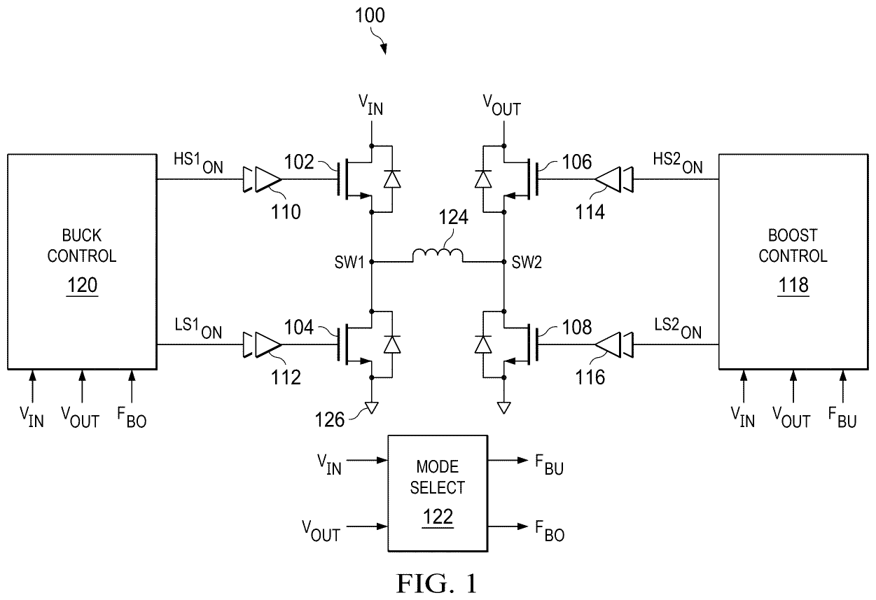

FIG. 1 is a block diagram of an example switching converter 100. The switching converter 100 is a constant on-time buck-boost switching converter. The switching converter 100 includes transistors 102, 104, 106, and 108, drivers 110, 112, 114, and 116, a boost control circuit 118, a buck control circuit 120, a mode select circuit 122, and an inductor 124. The transistors 102, 104, 106, and 108, the drivers 110, 112, 114, and 116, the boost control circuit 118, the buck control circuit 120, and the mode select circuit 122 may be provided on an integrated circuit. The transistors 102, 104, 106, and 108 may be n-channel field effect transistors (NFETs).

The transistor 102 has a first terminal (e.g., drain) coupled to a voltage input terminal (V_{IN}), a second terminal (e.g., source), and a control terminal (e.g., gate) coupled to the buck control circuit 120 via the driver 110. The transistor 104 has a first terminal (e.g., drain) coupled to the second terminal of the transistor 102, a second terminal (e.g., source) coupled to a reference terminal (e.g., ground 126), and a control terminal (e.g., gate) coupled to the buck control circuit 120 via the driver 112. The driver 110 receives a control signal HS1_{ON} from the buck control circuit 120, and provides an output signal based on HS1_{ON} with voltage and current suitable for controlling the transistor 102. The driver 112 receives a control signal LS1_{ON} from the buck control circuit 120, and provides an output signal based on LS1_{ON} with voltage and current suitable for controlling the transistor 104.

The buck control circuit 120 controls switching of the transistor 102 and the transistor 104 for buck and buck-boost mode operation of the switching converter 100. The buck control circuit 120 has an output coupled to the control terminal of the transistor 102 via the driver 110, at which HS1_{ON} is provided. The buck control circuit 120 also has an output coupled to the control terminal of the transistor 104 via the driver 112, at which LS1_{ON} is provided. The buck control circuit 120 has a first input coupled to V_{IN}, a second input coupled to a voltage output terminal (V_{OUT}), and a third input coupled to the mode select circuit 122 for receipt of a boost mode signal (F_{BO}). The buck control circuit 120 applies the voltages at V_{IN} and V_{OUT}, and the signal F_{BO} to control switching of the transistor 102 and transistor 104 in buck mode and buck-boost mode. For boost mode operation, the buck control circuit 120 may turn on the transistor 102 and turn off the transistor 104.

The transistor 106 has a first terminal (e.g., drain) coupled to V_{OUT}, a second terminal (e.g., source), and a control terminal (e.g., gate) coupled to the boost control circuit 118 via the driver 114. The transistor 108 has a first terminal (e.g., drain) coupled to the second terminal of the transistor 106, a second terminal (e.g., source) coupled to a reference terminal (e.g., ground 126), and a control terminal (e.g., gate) coupled to the boost control circuit 118 via the driver 116. The driver 114 receives a control signal HS2_{ON} from the boost control circuit 118, and provides an output signal based on HS2_{ON} with voltage and current suitable for controlling the transistor 106. The driver 116 receives a control signal LS2_{ON} from the boost control circuit 118, and provides an output signal based on LS2_{ON} with voltage and current suitable for controlling the transistor 108.

The boost control circuit 118 controls switching of the transistor 106 and the transistor 108 for boost and buck-boost mode operation of the switching converter 100. The boost control circuit 118 has an output coupled to the control terminal of the transistor 106 via the driver 114, at which HS2_{ON} is provided. The boost control circuit 118 has an output coupled to the control terminal of the transistor 108 via the driver 116, at which LS2_{ON} is provided. The boost control circuit 118 has a first input coupled to V_{IN}, a second input coupled to V_{OUT}, and a third input coupled to the mode select circuit 122 for receipt of a buck mode signal (F_{BU}). The boost control circuit 118 applies the voltages at V_{IN} and V_{OUT}, and the signal F_{BU} to control switching of the transistor 106 and transistor 108 in boost mode and buck-boost mode. For buck mode operation, the boost control circuit 118 may turn on the transistor 106, and turn off the transistor 108.

The inductor 124 has a first terminal coupled to the second terminal of the transistor 102, and a second terminal coupled to the second terminal of the transistor 106.

The mode select circuit 122 determines whether the switching converter 100 should operate buck mode, boost mode, or buck-boost mode. The mode select circuit 122 has a first input coupled to V_{IN} and a second input coupled to V_{OUT}. The mode select circuit 122 may compare the voltages provided on V_{IN} and V_{OUT} to determine an operational mode of the switching converter 100. The mode select circuit 122 has a first output at which F_{BU} is provided, where F_{BU} indicates whether the switching converter 100 is to operate in buck mode. The mode select circuit 122 has a second output at which F_{BO} is provided, where F_{BO} indicates whether the switching converter 100 is to operate in boost mode. The switching converter 100 will operate in buck-boost mode if F_{BU} and F_{BO} indicate that the switching converter 100 is not operating in buck mode or boost mode.

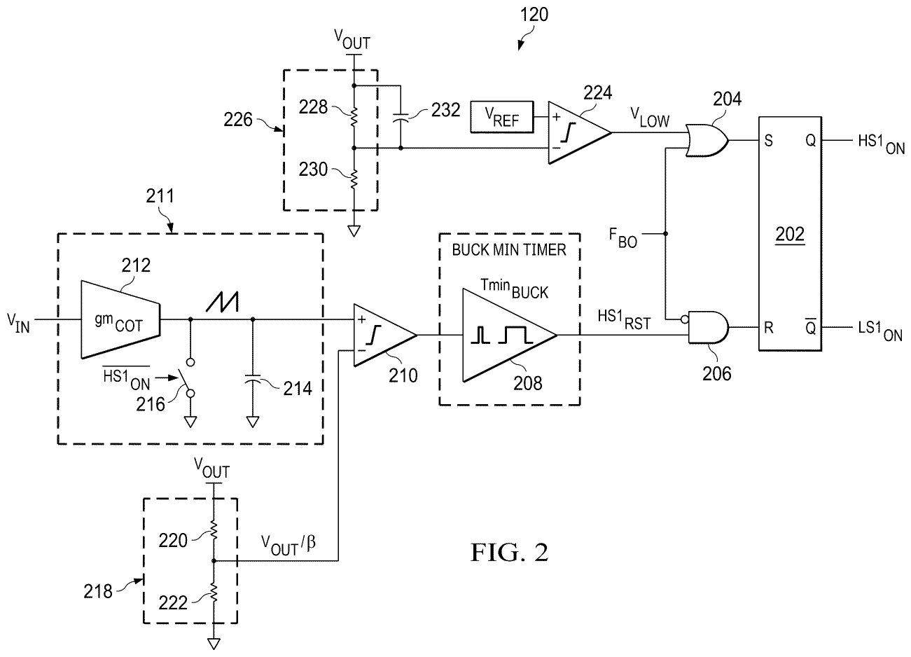

FIG. 2 is a schematic diagram of an example buck control circuit 120. The buck control circuit 120 includes a flip-flop 202, logic gates 204 and 206, a timer 208, comparators 210 and 224, a ramp circuit 211, voltage dividers 218 and 226, and a capacitor 232. The flip-flop 202 provides the switching control signals HS1_{ON} and LS1_{ON} for controlling the transistor 102 and the transistor 104. A first output of the flip-flop 202 provides HS1_{ON}, and is coupled to the control terminal of the transistor 102 via the driver 110. A second output of the flip-flop 202 provides LS1_{ON}, and is coupled to the control terminal of the transistor 104 via the driver 112. The logic gate 204 and the logic gate 206 gate control signals to the inputs of the flip-flop 202. The flip-flop 202 has a first input (e.g., set input) coupled to an output of the logic gate 204, and a second input (e.g., reset input) coupled to an output of the logic gate 206. The logic gate 204 has a first input coupled to the mode select circuit 122 for receipt of F_{BO}. A first input of the logic gate 206 is coupled to the first input of the logic gate 204. If F_{BO} has a state indicating that the switching converter 100 is operating in boost mode, then the logic gate 204 and logic gate 206 set the flip-flop 202 to turn on the transistor 102 and turn off the transistor 104.

The logic gate 204 has a second input coupled to the comparator 224. The comparator 224 generates a signal V_{LOW} that indicates whether the voltage at V_{OUT} is lower than a threshold. The comparator 224 has an output coupled to the second input of the logic gate 204, a first input coupled to a reference voltage circuit for receipt of a threshold voltage, and a second input coupled to the voltage divider 226. The voltage divider 226 divides the voltage at V_{OUT} by a divisor selected by the resistors 228 and 230. The comparator 224 compares the threshold voltage to the voltage at V_{OUT} divided by the voltage divider 226 to initiate a switching cycle. The capacitor 232 is coupled between the V_{OUT} and the second input of the 224 to provide filtering. The logic gate 204 passes V_{LOW} to the flip-flop 202 if F_{BO} indicates that the switching converter 100 is not operating in boost mode.

The logic gate 206 has a second input coupled to the timer 208 for receipt of a signal HS1_{RST}. HS1_{RST} controls turn off of the transistor 102 and turn on of the transistor 104. The timer 208 is a pulse generator, and has an output, at which HS1_{RST} is provided, that is coupled to the second input of the logic gate 206. HS1_{RST} is a pulse having a width (Tmin_{BUCK}) selected to turn on the transistor 104 for a desired minimum time. Tmin_{BUCK} may be fixed, and may be selected based on commutation time limitations of the transistors 102 and 104. The width of the HS1_{RST} pulse may be controlled by analog or digital timing circuits of the timer 208. The timer 208 has an input coupled to the comparator 210 for receipt of a signal that triggers the timer 208 to generate HS1_{RST}.

The comparator 210 has an output coupled to the input of the timer 208, a first input coupled to the ramp circuit 211, and a second input coupled to the voltage divider 218. The voltage divider 218 divides the voltage at V_{OUT} by a divisor (β) selected by the resistors 220 and 222. The ramp circuit 211 has an amplifier 212, a switch 216, and a capacitor 214. The gain (transconductance gm_{COT}) of the amplifier 212 may be adjustable and inversely proportional to a switching period (T_{SW}) of the switching converter 100. The amplifier 212 has an input coupled to V_{IN}, and an output coupled to the first input of the comparator 210. The switch 216 has a first terminal coupled to the output of the amplifier 212, a second terminal coupled to the reference terminal, and a control input coupled to the first output of the flip-flop 202 (e.g., via an inverter that is not shown). The capacitor 214 has a first terminal coupled to the output of the amplifier 212 and a second terminal coupled to the reference terminal. The switch 216 is closed to discharge the capacitor 214, and if the switch 216 is open the amplifier 212 charges the capacitor 214 to generate the ramp voltage. The comparator 210 triggers the timer 208 if the ramp voltage (the voltage across the capacitor 214) exceeds the voltage at V_{OUT} divided by the voltage divider 218.

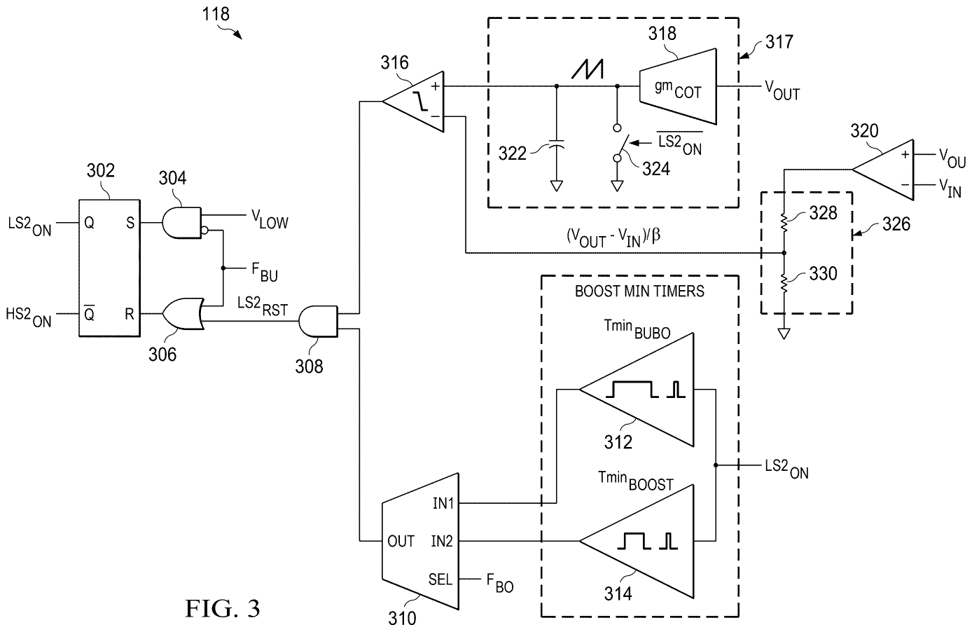

FIG. 3 is a schematic diagram of an example boost control circuit 118. The boost control circuit 118 includes a flip-flop 302, logic gates 304, 306 and 308, timers 312 and 314, a comparator 316, a multiplexer 310, a ramp circuit 317, a voltage divider 326, and an amplifier 320. The flip-flop 302 provides the switching control signals HS2_{ON} and LS2_{ON} for controlling the transistor 106 and the transistor 108. A first output of the flip-flop 302 provides HS2_{ON}, and is coupled to the control terminal of the transistor 106 via the driver 114. A second output of the flip-flop 302 provides LS2_{ON}, and is coupled to the control terminal of the transistor 108 via the driver 116. The logic gate 304 and the logic gate 306 gate control signals to the inputs of the flip-flop 302. The flip-flop 302 has a first input (e.g., set input) coupled to an output of the logic gate 304, and a second input (e.g., reset input) coupled to an output of the logic gate 306. The logic gate 304 has a first input coupled to the mode select circuit 122 for receipt of F_{BU}. A first input of the logic gate 306 is coupled to the first input of the logic gate 304. If F_{BU} has a state indicating that the switching converter 100 is operating in buck mode, then the logic gate 304 and logic gate 306 set the flip-flop 302 to turn on the transistor 106 and turn off the transistor 108.

The logic gate 304 has a second input coupled to the output of the comparator 224 for receipt of V_{LOW}. The logic gate 306 has a second input coupled to the logic gate 308 for receipt of a signal LS2_{RST}. LS2_{RST} controls turn off of the transistor 108 and turn on of the transistor 106. The logic gate 308 has an output, at which LS2_{RST} is provided, that is coupled to the second input of the logic gate 306. The logic gate 308 has a first input coupled to the comparator 316 and a second input coupled to the multiplexer 310. The multiplexer 310 selects the output signals of the timers 312 and 314 to reset the flip-flop 302. The multiplexer 310 has a first input coupled to the timer 312, a second input coupled to the timer 314, and a select input coupled to the mode select circuit 122 for receipt of F_{BO}. If F_{BO} indicates that the switching converter 100 is in boost mode, then the multiplexer 310 selects the output signal provided by the timer 314. If F_{BO} indicates that the switching converter 100 is not in boost mode, then the multiplexer 310 selects the output signal provided by the timer 312.

The timer 314 has an output coupled to the second input of the multiplexer 310. The output signal of the timer 314 is a pulse having a width (Tmin_{BOOST}) selected to turn off the transistor 108 for a desired minimum time in boost mode. Tmin_{BOOST} may be fixed, and may be selected based on commutation time limitations of the transistors 106 and 108. In some examples, Tmin_{BOOST} may be approximately equal to Tmin_{BUCK}. The width of the pulse provided by the timer 314 may be controlled by analog or digital timing circuits of the timer 314. The timer 314 has an input coupled to the first output of the flip-flop 302 for triggering the timer 314 to generate the pulse.

The timer 312 has an output coupled to the first input of the multiplexer 310. The output signal of the timer 312 is a pulse having a width (Tmin_{BUBO}) selected to turn off the transistor 108 for a desired minimum time in buck-boost mode. Tmin_{BUBO} may be fixed, and may be selected to minimize inductor current ripple and allow buck-boost operation without pulse skipping (with generation of a buck cycle for each boost cycle). In some examples, Tmin_{BUBO} may be about three times Tmin_{BOOST}. The width of the pulse provided by the timer 312 may be controlled by analog or digital timing circuits of the timer 312. The timer 312 has an input coupled to the first output of the flip-flop 302 for triggering the timer 312 to generate the pulse.

The logic gate 308 has a first input coupled to the multiplexer 310 for receipt of the signal provided by the multiplexer 310, a second input coupled to the comparator 316, and an output coupled to the second input of the logic gate 306. The comparator 316 has an output coupled to the second input of the logic gate 308, a first input coupled to the ramp circuit 317, and a second input coupled to the voltage divider 326. The voltage divider 326 divides a difference signal provided by the amplifier 320 by a divisor (β) selected by the resistors 328 and 330. The amplifier 320 has an output coupled to the voltage divider 326, a first input coupled to V_{OUT}, and a second input coupled to V_{IN}. The amplifier 320 provides a difference voltage representing the difference of the voltage at V_{OUT} and the voltage at V_{IN} to the voltage divider 326 for division, with the divided difference voltage provided to the second input of comparator 316.

The ramp circuit 317 has an amplifier 318, a switch 324, and a capacitor 322. The amplifier 318 has gain (transconductance) gm_{COT}. The amplifier 318 has an input coupled to V_{OUT}, and an output coupled to the first input of the comparator 316. The switch 324 has a first terminal coupled to the output of the amplifier 318, a second terminal coupled to the reference terminal, and a control input coupled to the second output of the flip-flop 302 (e.g., via an inverter that is not shown). The capacitor 322 has a first terminal coupled to the output of the amplifier 318 and a second terminal coupled to reference terminal. The switch 324 is closed to discharge the capacitor 322, and if the switch 324 is open the amplifier 318 charges the capacitor 322 to generate the ramp voltage. The comparator 316 compares the ramp voltage and divided V_{OUT} voltage, and enables the logic gate 308 to pass the pulse provided by the multiplexer 310 (and turn off the transistor 108) if the ramp voltage exceeds the divided V_{OUT} voltage.

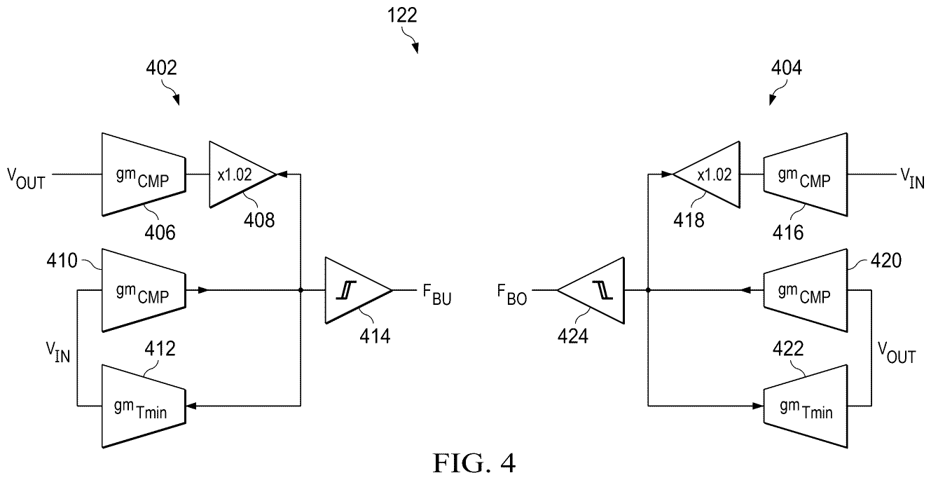

FIG. 4 is a schematic diagram of an example mode select circuit 122. The mode select circuit 122 includes a buck mode circuit 402 and a boost mode circuit 404. The buck mode circuit 402 includes amplifiers 406, 408, 410, and 412, and a buffer circuit 414. The amplifiers 406 and 408 have gain (transconductance) gm_{CMP}, where gm_{CMP} may be adjustable, and proportional to T_{SW}. The amplifier 406 has an input coupled to V_{OUT}, and an output coupled to the amplifier 408. The amplifier 408 has an input coupled to the output of the amplifier 406 and an output coupled to the buffer circuit 414. The amplifier 410 has an input coupled to V_{IN}, and an output coupled to the buffer circuit 414. The amplifier 412 has an input coupled to V_{IN}, and an output coupled to the buffer circuit 414. The buffer circuit 414 may be a Schmitt trigger. The buffer circuit 414 has an input coupled to the output of the amplifier 408, the output of the amplifier 410, and the output of the amplifier 412. An output of the buffer circuit 414 is coupled to the first input of the logic gate 304 and the first input of the logic gate 306. F_{BU} is provided at the output of the buffer circuit 414.

The boost mode circuit 404 includes amplifiers 416, 418, 420, and 422, and a buffer circuit 424. The amplifier 416 has an input coupled to V_{IN}, and an output coupled to the amplifier 418. The amplifier 418 has an input coupled to the output of the amplifier 416 and an output coupled to the buffer circuit 424. The amplifier 420 has an input coupled to V_{IN}, and an output coupled to the buffer circuit 424. The amplifier 422 has an input coupled to V_{IN}, and an output coupled to the buffer circuit 424. The buffer circuit 424 may be a Schmitt trigger. The buffer circuit 424 has an input coupled to the output of the amplifier 418, the output of the amplifier 420, and the output of the amplifier 422. An output of the buffer circuit 424 is coupled to the first input of the logic gate 204 and the first input of the logic gate 206. F_{BO} is provided at the output of the buffer circuit 424.

The transconductances of the amplifiers 406, 408, 410, 412, 416, 418, 420 and 422 are weighted according to a desired switching frequency of the switching converter 100. The output currents of the amplifiers 408, 410, and 412 are summed and provided at the input of the buffer circuit 414, and the output currents of the amplifiers 418, 420, and 422 are summed and provided at the input of the buffer circuit 424. In this way, the states of F_{BU} and F_{BO} are determined independent of switching frequency and the buck-boost region can be reduced to the point of power stage commutation time limitations only.

In some examples of the mode select circuit 122, the switching converter 100 may operate in buck mode (F_{BU} indicates buck mode) if:

$${V}_{IN} \geq {V}_{OUT} \frac{{T}_{SW}}{{T}_{S W} - {Tmin}_{BUCK}}$$

where:
V_{IN} is the voltage at the input terminal;
V_{OUT} is the voltage at the output terminal;
T_{SW} is switching period; and
Tmin_{BUCK} is the width of pulse generated by the timer 208.

In some examples of the mode select circuit 122, the switching converter 100 may operate in boost mode (F_{BO} indicates boost mode) if:

$${V}_{IN} \leq {V}_{OUT} \frac{{T}_{S W} - {Tmin}_{BOOST}}{{T}_{SW}}$$

where Tmin_{BOOST} is the width of pulse generated by the timer 314.

In some examples of the mode select circuit 122, the switching converter 100 may operate in buck-boost mode if:

$${V}_{IN} \geq {V}_{OUT} \frac{{Tmin}_{BUBO} - {T}_{SW}}{{Tmin}_{BUCK} - {T}_{SW}}$$

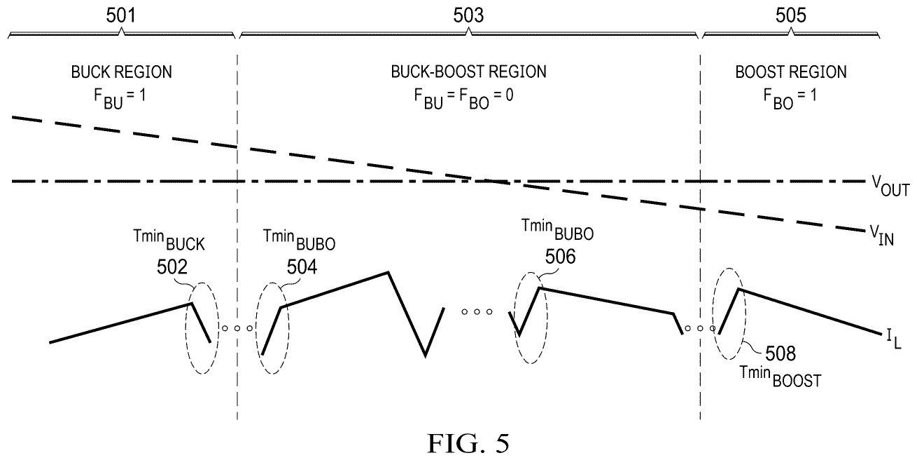

FIG. 5 shows examples of inductor current in the switching converter 100 in buck, buck-boost, and boost modes. Voltages at V_{IN} and V_{OUT}, and current in the inductor 124 (IL) are shown. In FIG. 5, the switching converter 100 is operating in buck mode in interval 501, in buck-boost mode in interval 503, and in boost mode in interval 505. In interval 501, the voltage at V_{IN} is greater than the voltage at V_{OUT} (e.g., by a selected amount), and the mode select circuit 122 sets F_{BU} to a value (e.g., a logic one) indicating that the switching converter 100 is operating in buck mode. Inductor current (IL) increases with the transistor 102 turned on, and decreases in the interval 502 with the transistor 104 turned on. The transistor 104 is turned on for a time Tmin_{BUCK} defined by the timer 208.

In interval 503, the voltage at V_{IN} is less than a threshold for buck mode operation, and above a threshold for boost mode operation. Accordingly, the mode select circuit 122 sets F_{BU} to a value (e.g., a logic zero) indicating that the switching converter 100 is not operating in buck mode, and sets F_{BO} to a value (e.g., a logic zero) indicating that the switching converter 100 is not operating in boost mode. In the interval 504, the transistor 108 is turned on, and inductor current increases for time Tmin_{BUBO} defined by the timer 312, to boost the voltage at V_{OUT}. Thereafter, the transistor 104 is turned on to regulate the voltage at V_{OUT}. Similarly, in the interval 506, the transistor 108 is turned on, and inductor current increases for time Tmin_{BUBO} defined by the timer 312, to boost the voltage at V_{OUT}. Thereafter, the transistor 104 is turned on to regulate the voltage at V_{OUT}. Because V_{IN} is higher in the interval 504 than in the interval 506, the current flowing through the transistor 104 following the interval 504 is greater than the current flowing through the transistor 104 following the interval 506.

In interval 505, the voltage at V_{IN} is less than the voltage at V_{OUT} (e.g., by a selected amount), and the mode select circuit 122 sets F_{BO} to a value (e.g., a logic one) indicating that the switching converter 100 is operating in boost mode. In the interval 508, the transistor 108 is turned on, and inductor current increases for time Tmin_{BOOST} defined by the timer 314, to boost the voltage at V_{OUT}.

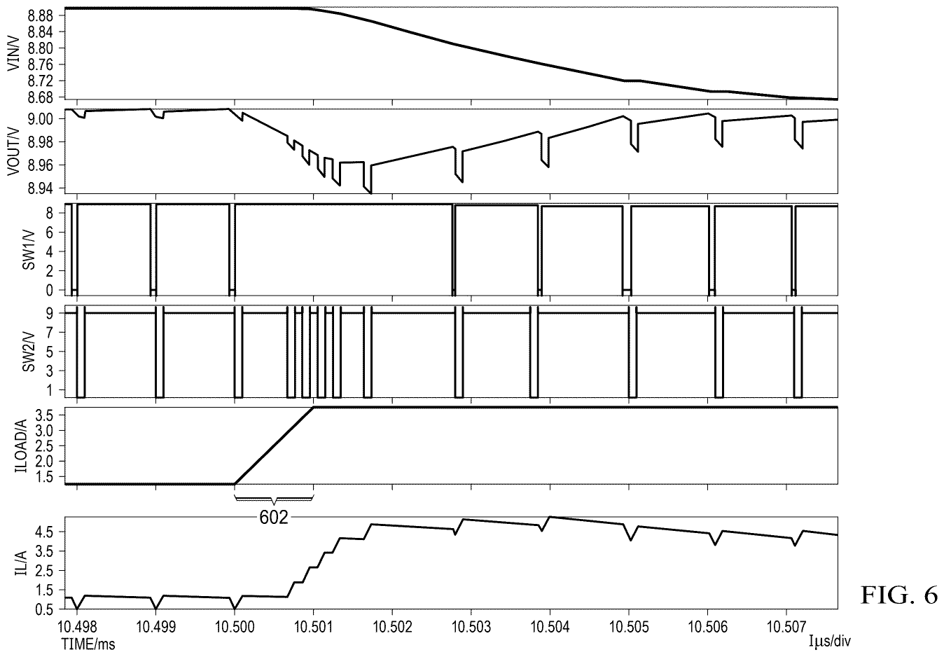

FIG. 6 is a graph of signals during buck-boost operation of the switching converter 100. FIG. 6 shows the voltages at V_{IN} and V_{OUT}, the voltages at switch nodes SW1 and SW2, the load current (ILOAD), and the current in the inductor 124 (IL). In the interval 602, ILOAD increases from 1 ampere to 4 amperes, and the voltage at V_{OUT} drops. In response to the drop in voltage at V_{OUT}, the frequency of switching at SW2 increases, and IL increases to boost the voltage at V_{OUT}. As the voltage at V_{OUT} drops and the switching at SW2 increases, switching at SW1 is suspended until the switching at SW2 increases the voltage at V_{OUT}. Thereafter, switching at SW1 is resumed to regulate V_{OUT}.

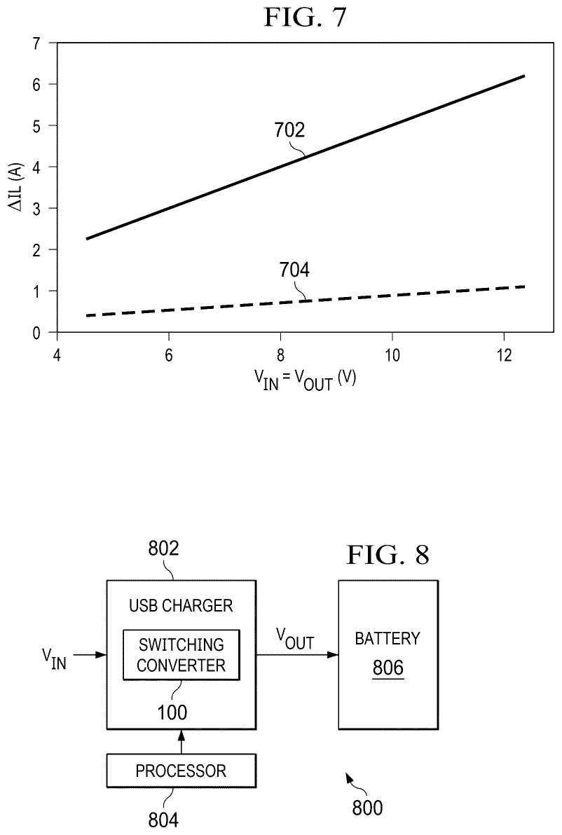

FIG. 7 is a graph comparing example ripple current in the switching converter 100 to ripple current in a buck-boost converter using four transistor switching. In FIG. 7, the x-axis represents V_{IN} and V_{OUT} in volts, where V_{IN}=V_{OUT}, and the y-axis represents current ripple in amperes. The curve 702 represents the ripple current of the buck-boost converter using four transistor switching, and the curve 704 represents the ripple current of the switching converter 100 (which uses two transistor switching). FIG. 7 shows that the current ripple of the switching converter 100 is significantly lower (e.g., curve 702 is 4-6 times higher) than the current ripple of the buck-boost converter using four transistor switching in the illustrated voltage range.

In an example of the switching converter 100, the maximum ripple current in buck-boost operation is expressed as:

$${I}_{L - ripple} = \frac{{V}_{OUT}}{L} ( {Tmin}_{BUCK} + {Tmin}_{BUBO} - \frac{{Tmin}_{BUBO} {Tmin}_{BUCK}}{{T}_{SW}} )$$

where L is the inductance of the inductor 124.

FIG. 8 is a block diagram of an example battery charging system 800. The battery charging system 800 includes a USB charger 802, a processor 804, and a battery 806. The USB charger 802 charges the battery 806 using voltage V_{IN}. V_{IN} may be received via a USB-PD cable, or other conductors. The battery 806 may be included in a mobile electronic device, such as a notebook computer, a tablet computer, a smartphone, or any other battery powered device. The processor 804 may be a microcontroller, a general purpose processor, or other processor. The processor 804 is coupled to the USB charger 802, and may provide control and status monitoring for charging the battery 806.

The USB charger 802 includes the switching converter 100. The switching converter 100 generated an output voltage V_{OUT} based on the input voltage V_{IN} for charging the battery 806. The switching converter 100 enables the USB charger 802 to charge the battery 806 using a wide range of input voltages with buck, boost, and buck-boost modulation and provides the fast transient response of COT control.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a first transistor having a first terminal, a second terminal, and a control terminal;
a second transistor having a first terminal coupled to the second terminal of the first transistor, a second terminal coupled to a reference terminal, and a control terminal;
a third transistor having a first terminal, a second terminal, and a control terminal;
a fourth transistor having a first terminal coupled to the second terminal of the third transistor, a second terminal coupled to the reference terminal, and a control terminal;
a first control circuit having a first output coupled to the control terminal of the first transistor, and a second output coupled to the control terminal of the second transistor;
a second control circuit including:
a flip-flop having a first output coupled to the control terminal of the third transistor, a second output coupled to the control terminal of the fourth transistor, and an input;
a first timer having an output coupled to the input of the flip-flop; and
a second timer having an output coupled to the input of the flip-flop.

2. The circuit of claim 1, wherein the second control circuit includes a multiplexer having a first input coupled to the output of the first timer, a second input coupled to the output of the second timer, and an output coupled to the first input of the flip-flop.

3. The circuit of claim 1, wherein:
the flip-flop is a first flip-flop; and
the first control circuit includes:
a second flip-flop having a first output coupled to the control terminal of the first transistor, a second output coupled to the control terminal of the second transistor, and an input; and
a third timer having an output coupled to the input of the second flip-flop.

4. The circuit of claim 3, wherein:
the input of the second flip-flop is a first input;
the second flip-flop has a second input;
the third timer has an input; and
the first control circuit includes:
a first comparator having a first input coupled to the first terminal of the third transistor, a second input coupled to a reference voltage circuit, and an output coupled to the second input of the second flip-flop;
an amplifier having an input coupled to the first terminal of the first transistor, and an output; and
a second comparator having a first input coupled to the first terminal of the third transistor, a second input coupled to the output of the amplifier, and an output coupled to the second input of the second flip-flop.

5. The circuit of claim 4, wherein:
the amplifier is a first amplifier;
the first flip-flop has a second input coupled to the output of the first comparator; and
the second control circuit includes:
a second amplifier having an input coupled to the first terminal of the third transistor, and an output;
a third amplifier having a first input coupled to the first terminal of the third transistor, a second input coupled to the first terminal of the first transistor, and an output; and
a third comparator having a first input coupled to the output of the second amplifier, a second input coupled to the output of the third amplifier, and an output coupled to the first input of the first flip-flop.

6. The circuit of claim 4, wherein:
the first control circuit is a buck control circuit;
the second control circuit is a boost control circuit; and
the circuit further comprises a mode select circuit including:
a buck mode circuit including:
a buffer circuit having an input, and an output coupled to the first input and the second input of the first flip-flop;
a fourth amplifier having an input coupled to the first terminal of the third transistor, and an output coupled to the input of the buffer circuit;
a fifth amplifier having an input coupled to first terminal of the first transistor, and an output coupled to the input of the buffer circuit; and
a sixth amplifier having an input coupled to the first terminal of the first transistor, and an output coupled to the input of the buffer circuit.

7. The circuit of claim 6, wherein:
the buffer circuit is a first buffer circuit; and
the mode select circuit includes:
a boost mode circuit including:
a second buffer circuit having an input, and an output coupled to the first input and the second input of the second flip-flop;
a seventh amplifier having an input coupled to the first terminal of the first transistor, and an output coupled to the input of the second buffer circuit;
an eighth amplifier having an input coupled to first terminal of the third transistor, and an output coupled to the input of the second buffer circuit; and
a ninth amplifier having an input coupled to the first terminal of the third transistor, and an output coupled to the input of the second buffer circuit.

8. An apparatus, comprising:
a first transistor having a first terminal, a second terminal, and a control terminal;
a second transistor having a first terminal coupled to the second terminal of the first transistor, a second terminal coupled to a reference terminal, and a control terminal;
a third transistor having a first terminal, a second terminal, and a control terminal;
a fourth transistor having a first terminal coupled to the second terminal of the third transistor, a second terminal coupled to the reference terminal, and a control terminal;
a buck control circuit having a first output coupled to the control terminal of the first transistor, and a second output coupled to the control terminal of the second transistor;
a boost control circuit having a first output coupled to the control terminal of the third transistor, and a second output coupled to the control terminal of the fourth transistor, the boost control circuit including:
a first timer configured to turn off the fourth transistor responsive to the apparatus operating in a boost mode; and
a second timer configured to turn off the fourth transistor responsive to the apparatus operating in a buck-boost mode.

9. The apparatus of claim 8, wherein the buck control circuit includes a third timer configured to turn off the first transistor responsive to the apparatus operating in a buck mode or the buck-boost mode.

10. The apparatus of claim 9, wherein the buck control circuit includes:
a ramp circuit configured to provide a ramp voltage based on a voltage at the first terminal of the first transistor; and
a comparator having an output coupled to an input of the third timer, the comparator configured to compare the ramp voltage to a voltage at the first terminal of the third transistor.

11. The apparatus of claim 8, wherein the boost control circuit includes a multiplexer configured to select the first timer to turn off the fourth transistor based on the apparatus operating in the boost mode, and select the second timer to turn off the fourth transistor based on the apparatus not operating in the boost mode.

12. The apparatus of claim 8, wherein:
the buck control circuit includes a comparator configured to compare a voltage at the first terminal of the third transistor to a reference voltage; and
the buck control circuit is configured to turn on the first transistor based on an output signal provided by the comparator.

13. The apparatus of claim 8, wherein:
the boost control circuit includes:
an amplifier configured to provide a difference signal based on a difference of a voltage at the first terminal of the third transistor and a voltage at the first terminal of the first transistor;
a ramp circuit configured to provide a ramp voltage based on the voltage at the first terminal of the third transistor; and
a comparator configured to compare the ramp voltage to the difference signal; and
the boost control circuit is configured to turn off the fourth transistor based on an output signal provided by the comparator.

14. The apparatus of claim 8, further comprising a buck mode circuit configured to determine whether the apparatus is to operate in buck mode based on a voltage at the first terminal of the first transistor and a voltage at the first terminal of the third transistor.

15. The apparatus of claim 8, further comprising a boost mode circuit configured to determine whether the apparatus is to operate in boost mode based on a voltage at the first terminal of the first transistor and a voltage at the first terminal of the third transistor.

16. A system, comprising:
an input terminal configured to receive an input voltage;
an output terminal configured to provide an output voltage;
a first transistor having a first terminal coupled to the input terminal, a second terminal, and a control terminal;
a second transistor having a first terminal coupled to the second terminal of the first transistor, a second terminal coupled to a reference terminal, and a control terminal;
a third transistor having a first terminal coupled to the output terminal, a second terminal, and a control terminal;
a fourth transistor having a first terminal coupled to the second terminal of the third transistor, a second terminal coupled to the reference terminal, and a control terminal;
an inductor having a first terminal coupled to the first terminal of the second transistor, and a second terminal coupled to the first terminal of the fourth transistor;
a buck control circuit having a first output coupled to the control terminal of the first transistor, and a second output coupled to the control terminal of the second transistor, the buck control circuit including a first timer configured to turn off the first transistor responsive to the system operating in a buck mode or a buck-boost mode; and
a boost control circuit having a first output coupled to the control terminal of the third transistor, and a second output coupled to the control terminal of the fourth transistor, the boost control circuit including:
a second timer configured to turn off the fourth transistor responsive to the system operating in a boost mode; and
a third timer configured to turn off the fourth transistor responsive to the system operating in a buck-boost mode.

17. The system of claim 16, wherein the buck control circuit includes:
a ramp circuit configured to provide a ramp voltage based on the input voltage;
a first comparator having an output coupled to an input of the third timer, the first comparator configured to compare the ramp voltage to the output voltage; and
a second comparator configured to compare the output voltage to a reference voltage, and the buck control circuit is configured to turn on the first transistor based on an output signal provided by the second comparator.

18. The system of claim 16, wherein the boost control circuit includes a multiplexer configured to select the second timer to turn off the fourth transistor based on the system operating in the boost mode, and select the third timer to turn off the fourth transistor based on the system not operating in the boost mode.

19. The system of claim 16, wherein:
the boost control circuit includes:
an amplifier configured to provide a difference signal based on a difference of the output voltage and the input voltage;
a ramp circuit configured to provide a ramp voltage based on the output voltage; and
a comparator configured to compare the ramp voltage to the difference signal; and
the boost control circuit is configured to turn off the fourth transistor based on an output signal provided by the comparator.

20. The system of claim 16, further comprising:
a buck mode circuit configured to determine whether the system is to operate in buck mode based on the input voltage and the output voltage; and
a boost mode circuit configured to determine whether the system is to operate in boost mode based on the input voltage and the output voltage.
